(19) United States
(12) Patent Application Publication
(10) Pub. No.: US 2025/0294723 A1
(43) Pub. Date: Sep. 18, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Wei XU, Wuhan (CN); Wei LIU, Wuhan (CN); Zongliang HUO, Wuhan (CN); Wenbin ZHOU, Wuhan (CN); Beibei LI, Wuhan (CN)

(21) Appl. No.: 18/623,419

(22) Filed: Apr. 1, 2024

Related U.S. Application Data
(63) Continuation of application No. PCT/CN2024/081701, filed on Mar. 14, 2024.

(51) Int. Cl. H10B 12/00

(52) U.S. Cl. CPC H10B 12/33; H10B 12/05; H10B 12/482; H10B 12/485

(57) ABSTRACT

Three-dimensional (3D) memory devices and fabricating methods are provided. In some implementations, a disclosed semiconductor device is a memory device and comprises an array of memory cells in an array region, word lines extending parallel in a first lateral direction, bit lines extending parallel in a second lateral direction different from the first lateral direction, and interconnection structures located within the array region and coupled with the bit lines, and arranged in staggered rows along the first lateral direction.

### CROSS-REFERENCE TO RELATED APPLICATIONS

This application is a continuation of International Application No. PCT/CN2024/081701, filed on Mar. 14, 2024, entitled “SEMICONDUCTOR DEVICES AND FABRICATING METHODS THEREOF,” which is incorporated herein by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

One aspect of the present disclosure provides a memory device, comprising: an array of memory cells in an array region; word lines extending parallel in a first lateral direction; bit lines extending parallel in a second lateral direction different from the first lateral direction; and interconnection structures located within the array region and coupled with the bit lines, and arranged in staggered rows along the first lateral direction.

In some implementations, a first distance between two interconnection structures coupled with two adjacent bit lines is greater than a second distance between the two adjacent bit lines.

In some implementations, a first row of interconnection structures are located at a first side of a center position of the array region; and a second row of interconnection structures are located at a second side of the center position opposite to the first side.

In some implementations, a first row of interconnection structures are located at a first side of one word line; and a second row of interconnection structures are located at a second side of the one word line opposite to the first side.

In some implementations, a third distance between the first row of interconnection structures and the center position is equal to a fourth distance between the second row of interconnection structures and the center position.

In some implementations, a third distance between the first row of interconnection structures and the center position is different from a fourth distance between the second row of interconnection structures and the center position.

In some implementations, a first row of interconnection structures and a second row of interconnection structures are located at a same side of a center position of the array region.

In some implementations, each of the array of memory cells comprises a vertical transistor and a storage unit coupled with the vertical transistor; and gate structures of each row of vertical transistors aligned along the first lateral direction are connected with each other to constitute a corresponding word line.

In some implementations, the gate structures of each row of vertical transistors are located on a lateral side of channel structures of the row of vertical transistors.

In some implementations, each gate structure laterally surrounds a corresponding channel structure.

In some implementations, the memory device further comprises: a conductive layer connected to first ends of the interconnection structures, wherein second ends of the interconnection structures are connected to the bit lines.

In some implementations, the memory device further comprises: an insulating layer between the bit lines and the conductive layer, wherein the interconnection structures vertically extend through the insulating layer.

In some implementations, the memory device further comprises insulating layers between bit lines, wherein second ends of the interconnection structures are laterally separated by the insulating layers.

Another aspect of the present disclosure provides a method of forming a memory device, comprising: forming bit lines extending parallel in a second lateral direction on a semiconductor layer; forming sacrificial structures each vertically extending through a corresponding bit line and into the semiconductor layer; forming an array of memory cells on the bit lines; removing the semiconductor layer to expose portions of the sacrificial structures; replacing the sacrificial structures with interconnection structures; and forming a conductive layer coupled with the interconnection structures.

In some implementations, the method further comprises: forming air gaps between adjacent bit lines.

In some implementations, forming the sacrificial structures comprises: forming rows of sacrificial structures aligned parallel along a first lateral direction, wherein adjacent rows of sacrificial structures are arranged in a staggered form.

In some implementations, the method further comprises: forming the array of memory cells comprises: forming an array of vertical transistors, each column of the vertical transistors along the second lateral direction are coupled with a corresponding one of the bit lines; and forming an array of storage units on the array of vertical transistors.

In some implementations, forming the array of vertical transistors comprises: forming an array of vertical channel structures on the array of semiconductor pillars; and forming a conductive structure at a side of a row of the array of vertical channel structures and along the first lateral direction.

In some implementations, forming the conductive structure comprises: forming the conductive structure to laterally surround each channel structure in the row.

In some implementations, the method further comprises: after removing the semiconductor layer, oxidizing exposed surfaces of the bit lines to form insulating layers.

Another aspect of the present disclosure provides a method of forming a memory device, comprising: forming bit lines extending parallel in a second lateral direction on a semiconductor layer; forming interconnection structures each vertically extending through a corresponding bit line and into the semiconductor layer; forming an array of memory cells on the bit lines; removing the semiconductor layer to expose portions of the interconnection structures; and forming a conductive layer coupled with the interconnection structures.

In some implementations, the method further comprises: forming insulating layers on sidewalls of the bit lines; and forming air gaps between adjacent bit lines.

In some implementations, forming the interconnection structures comprises forming rows of interconnection structures aligned parallel along a first lateral direction; and adjacent rows of interconnection structures are arranged in a staggered form.

In some implementations, forming the array of memory cells comprises: forming an array of vertical transistors, each column of the vertical transistors along the second lateral direction are coupled with a corresponding one of the bit lines; and forming an array of storage units on the array of vertical transistors.

In some implementations, forming the array of vertical transistors comprises: forming an array of vertical channel structures on the array of semiconductor pillars; and forming a conductive structure at a side of a row of the array of vertical channel structures and along the first lateral direction.

In some implementations, forming the conductive structure comprises: forming the conductive structure to laterally surround each channel structure in the row.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including an array of memory cells each having a vertical transistor, according to some implementations of the present disclosure.

FIG. 2A illustrates a schematic plan view of a memory device, according to some implementations of the present disclosure.

FIG. 2B illustrates a schematic plan view of a memory device, according to some implementations of the present disclosure.

FIG. 3A illustrates a schematic plan view of a portion of a memory device, according to some implementations of the present disclosure.

FIG. 3B illustrates a schematic side cross-sectional view of a cross-section of a portion of a memory device, according to some implementations of the present disclosure.

FIG. 3C illustrates a schematic side cross-sectional view of a cross-section of a portion of a memory device, according to some implementations of the present disclosure.

FIG. 4A illustrates a schematic plan view of a portion of a memory device, according to some implementations of the present disclosure.

FIG. 4B illustrates a schematic side cross-sectional view of a cross-section of a portion of a memory device, according to some implementations of the present disclosure.

FIG. 4C illustrates a schematic side cross-sectional view of a cross-section of a portion of a memory device, according to some implementations of the present disclosure.

FIG. 5 illustrates a block diagram of a system having a memory device, according to some implementations of the present disclosure.

FIG. 6 illustrates a flowchart of a fabricating method for forming a 3D memory device, according to some implementations of the present disclosure.

FIGS. 7A-7H each illustrates a schematic side cross-sectional view of a 3D memory device at a certain fabricating stage of the method shown in FIG. 6, according to various implementations of the present disclosure.

FIG. 8 illustrates a flowchart of a fabricating method for forming a 3D memory device, according to some implementations of the present disclosure.

FIGS. 9A-9H each illustrates a schematic side cross-sectional view of a 3D memory device at a certain fabricating stage of the method shown in FIG. 8, according to various implementations of the present disclosure.

FIG. 10 illustrates a flowchart of a fabricating method for forming a 3D memory device, according to some implementations of the present disclosure.

FIGS. 11A-11H each illustrates a schematic side cross-sectional view of a 3D memory device at a certain fabricating stage of the method shown in FIG. 10, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM). In a one-transistor-one-capacitor (1T1C) DRAM structure, the data are stored in the capacitors. In traditional DRAM architectures, the bit lines (BL) are usually buried at a bottom layer beneath the transistors and the capacitors, which cause significant BL-BL parasitic capacitance. Further, the BL routing interconnections in contact with the bit lines are generally located on both sides of the array. The Back-End-of-Line (BEOL) routing also contributes significantly to the parasitic capacitance. To meet the Sense Margin requirements, the capacitors require a substantial large capacitance, posing significant challenges in terms of process difficulty, and increasing difficulty to further shrinkage with the continuous scaling development of DRAM.

To address one or more of the aforementioned issues, the present disclosure introduces a solution in which a pre-buried BL method is applied. Specifically, in some implementations, periodic metal vias can be embedded during the Front-End-of-Line (FEOL) process. In some other implementations, periodic sacrificial vias can be embedded during the FEOL process, and then be replaced with metal in a subsequent process. In the BEOL process, the metal vias of adjacent two bit lines can be routed out alternately through a metal line layer. In some implementations, two or more layers of metal lines may be applied to form the bit line interconnection structures to further reduce the parasitic capacitance. By completing the vias in the FEOL process, overlay (OVL) issues in the BEOL process can be avoided, enabling the interconnection pickup of a grid-like layout of bit lines. The disclosed solution can significantly reduce the BL-BL parasitic capacitance, thereby lowering the capacitance requirements for the capacitors, reducing the difficulty of capacitor fabrication, and opening up pathways for further shrinkage with the continuous scaling development of DRAM.

Consistent with the scope of the present disclosure, according to some implementations of the present disclosure, the memory cell array having vertical transistors each comprising a semiconductor layer extending in a vertical direction, and a gate structure beside the semiconductor layer or surrounded by the semiconductor layer. In some implementations, the word lines and bit lines connected to the vertical transistors are arranged along a first lateral direction and a second lateral direction, respectively. Each of the semiconductor bodies of the array of vertical transistors extends along a vertical direction. By using such an arrangement, memory area efficiency can be increased. Further, the memory cell array and the peripheral circuits can be formed separately on different wafers, such that the fabricating processes of the memory cell array and the peripheral circuits do not affect each other, and the memory area efficiency can be further increased.

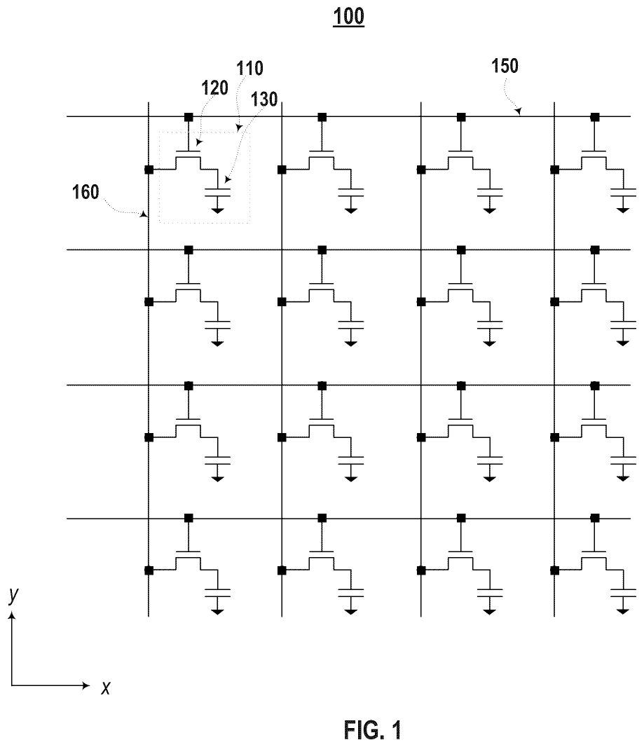

FIG. 1 illustrates a schematic diagram of a memory device 100 having an array of memory cells each having a vertical transistor, according to some implementations of the present disclosure. Memory device 100 can include a memory cell array in which each memory cell 110 includes a vertical transistor 120 and a storage unit coupled to vertical transistor 120. In some implementations as shown in FIG. 1, the memory cell array is a DRAM cell array, and the storage unit is a capacitor 130 for storing charge as the binary information stored by the respective DRAM cell. In some other implementations not shown in the figures, the memory cell array is a PCM cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 can be arranged in a two-dimensional (2D) array having rows and columns. Memory device 100 can include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground.

Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

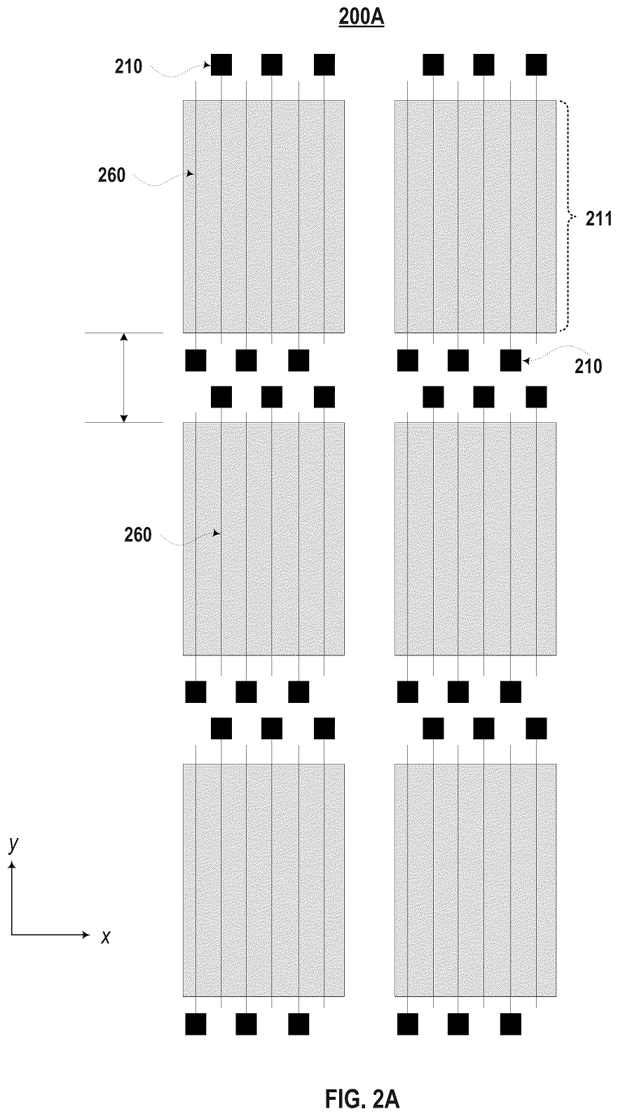

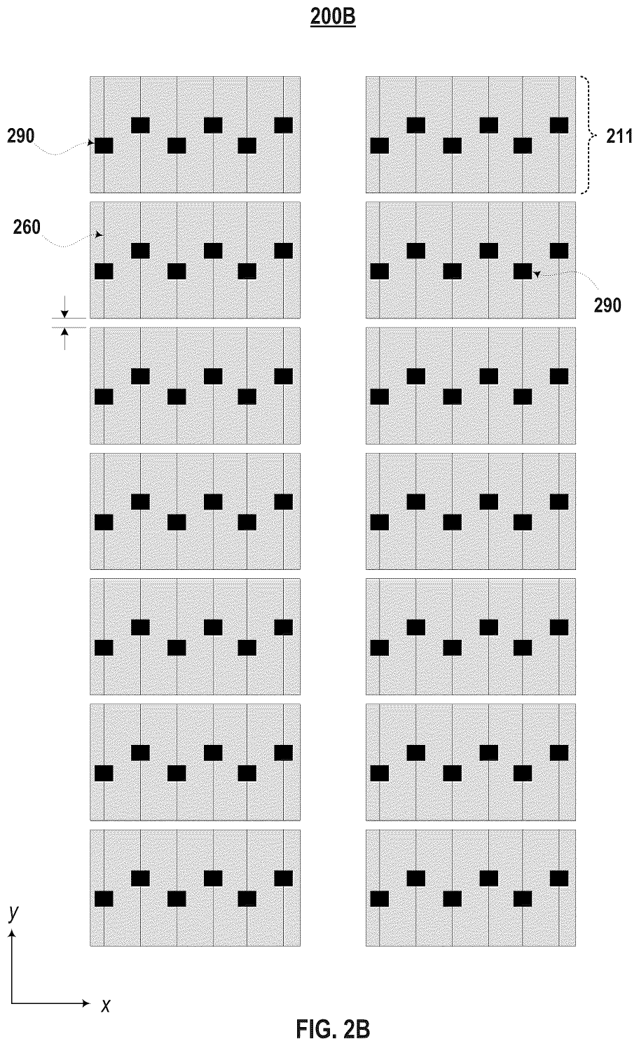

FIG. 2A illustrates a schematic plan view of a memory device 200A comprising a plurality of memory arrays 211 in the x-y plane, according to some implementations of the present disclosure. Each memory array 211 can include an array of memory cells each including a vertical transistor and a vertical capacitor. The vertical transistor can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc.

As shown in FIG. 2A, each memory array 211 can include a plurality of bit lines 260 each extending in a second lateral direction (the y-direction, referred to as the bit line direction). It is noted that, each memory array 211 can further include a plurality of word lines (not shown) each extending in a first lateral direction (the x-direction, referred to as the word line direction) perpendicular to the second lateral direction. The word lines and bit lines 260 may be formed in different lateral planes for case of routing. In some implementations, memory device 200A can further comprise a plurality of bit line interconnection structures 210 located at both sides of each memory array 211 along the bit line direction (the y-direction). The bit lines 260 can be interconnected to the bit line interconnection structures 210 in a staggered manner at both sides of each memory array 211 along the bit line direction (the y-direction). For example, a first group of bit line interconnection structures 210 located at a first side of each memory array 211 can be connected to the odd numbers of bit lines 260, and a second group of bit line interconnection structures 210 located at a second side of each memory array 211 can be connected to the even numbers of bit lines 260.

Such a layout may require a relatively large space between adjacent memory arrays 211 to locate the bit line interconnection structures 210. For example, the region between adjacent memory arrays 211 for locating the bit line interconnection structures 210 can occupy approximately 5% of the total area of the memory device, making it difficult to downsize the memory arrays 211 because this proportion increases when downsizing the memory arrays 211. Further, due to the bit lines 260 being driven via the bit line interconnection structures 210 on both ends, the lead-out resistance of the bit lines 260 can be relatively high, resulting in substantial resistive-capacitive (RC) delay. Additionally, the wiring of the bit line driving wires contributes significantly to parasitic capacitance due to being driven on both ends.

FIG. 2B illustrates a schematic plan view of a memory device 200B comprising a plurality of memory arrays 211 in the x-y plane, according to some implementations of the present disclosure. Each memory array 211 can include an array of memory cells each including a vertical transistor and a vertical capacitor. The vertical transistor can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc.

As shown in FIG. 2B, each memory array 211 can include a plurality of bit lines 260 each extending in the second lateral direction (the y-direction). It is noted that, each memory array 211 can further include a plurality of word lines (not shown) each extending in the first lateral direction (the x-direction). The word lines and bit lines 260 may be formed in different lateral planes for case of routing. In some implementations, memory device 200B can further comprise a plurality of bit line interconnection structures 290 located within the array region and coupled with the bit lines 260, and arranged in staggered rows along the first lateral direction (the x-direction). The bit lines 260 can be interconnected to the corresponding bit line interconnection structures 290 in a staggered manner. For example, a first row of bit line interconnection structures 290 aligned along the first lateral direction can be connected to the even numbers of bit lines 260, respectively, while a second row of bit line interconnection structures 290 aligned along the first lateral direction can be connected to the odd numbers of bit lines 260, respectively, as shown in FIG. 2B.

Such a layout does not require a relatively large space between adjacent memory arrays 211 to locate the bit line interconnection structures 290. For example, the region between adjacent memory arrays 211 can occupy approximately 0.5% of the total area of the memory device, making it easy to downsize the memory arrays 211 to decrease capacitance. Further, due to the bit lines 260 being driven via the bit line interconnection structures 290 from the center of the memory array 211, the routing resistance of the bit lines 260 can be relatively low, resulting in a reduced RC delay.

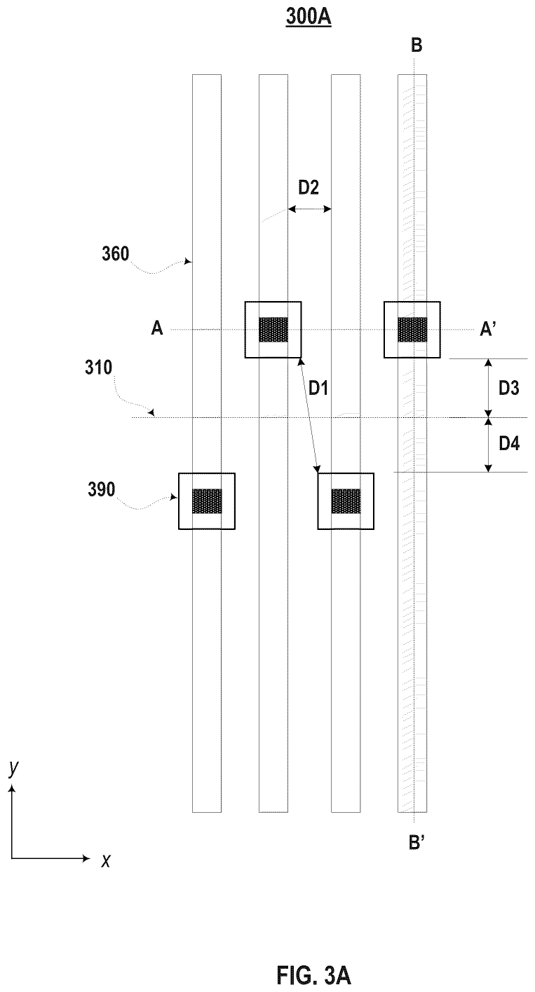

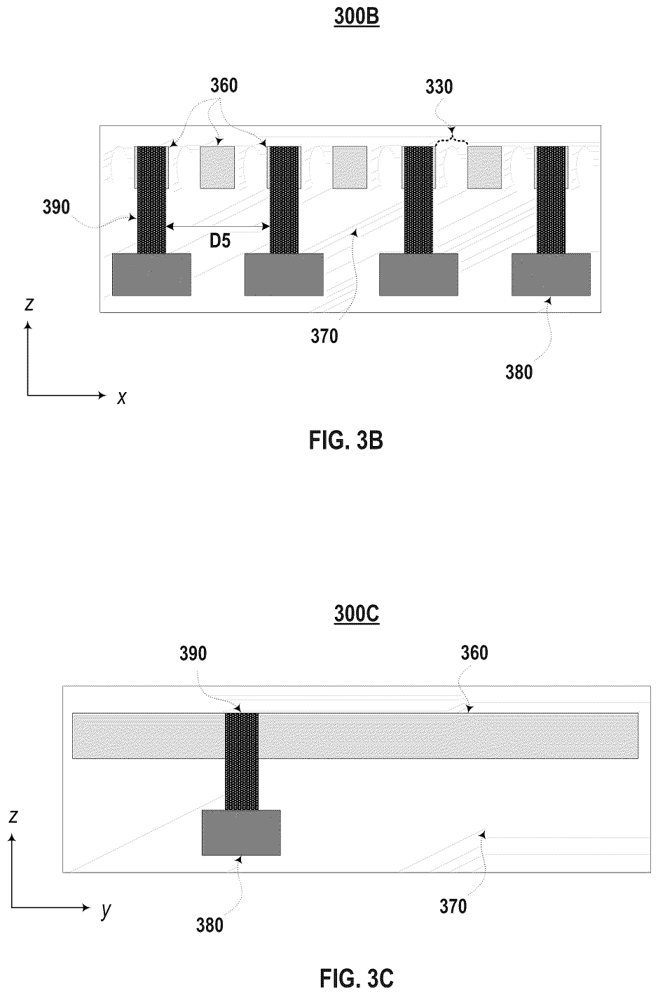

FIG. 3A illustrates a schematic plan view of a memory array 300A in the x-y plane, according to some implementations of the present disclosure. As shown in FIG. 3A, a plurality of bit lines 360 extend in parallel along the second lateral direction (the y-direction). It is noted that, memory array 300A further includes a plurality of word lines (not shown) extend in parallel along the first lateral direction (the x-direction). The word lines and bit lines 360 may be formed in different lateral planes for ease of routing. In some implementations, memory array 300A further comprises a plurality of bit line interconnection structures 390 located within the array region and coupled with the bit lines 360, and arranged in staggered rows along the first lateral direction (the x-direction). The bit lines 360 can be interconnected to the corresponding bit line interconnection structures 390 in a staggered manner.

In some implementations, a first distance DI between two bit line interconnection structures 390 coupled with two adjacent bit lines 360 is greater than a second distance D2 between the two adjacent bit lines 360, as shown in FIG. 3A. In some implementations, a first row of bit line interconnection structures 390 aligned along the first lateral direction can be connected to the even numbers of bit lines 360, respectively, while a second row of bit line interconnection structures 390 aligned along the first lateral direction can be connected to the odd numbers of bit lines 360, respectively.

As shown in FIG. 3A, the first row of bit line interconnection structures 390 can be located at a first side of a center line 310 of the array region of memory array 300A, and the second row of bit line interconnection structures 390 can be located at a second side of the center line 310 of the array region of memory array 300A opposite to the first side. In some implementations, a third distance D3 between the first row of bit line interconnection structures 390 and the center line 310 is equal to a fourth distance D4 between the second row of bit line interconnection structures 390 and the center line 310. In some other implementations, the third distance D3 between the first row of bit line interconnection structures 390 and the center line 310 is different from the fourth distance D4 between the second row of bit line interconnection structures 390 and the center line 310. In some other implementations not shown in the figures, the first row of bit line interconnection structures 390 and the second row of bit line interconnection structures 390 can be located at the same side of a center line 310 of the array region of memory array 300A.

FIG. 3B illustrates a schematic side cross-sectional view 300B in the x-z plane of memory array 300A along AA′ line shown in FIG. 3A, according to some implementations of the present disclosure. FIG. 3C illustrates a schematic side cross-sectional view 300C in the y-z plane of memory array 300A along BB′ line shown in FIG. 3A, according to some implementations of the present disclosure. As shown in FIGS. 3B and 3C, a row of bit line interconnection structures 390 along the first lateral direction (the x-direction) can be alternatively connected between corresponding even/odd number bit lines 360 and a conductive layer 380 (e.g., a BEOL metal layer). For example, the first ends of bit line interconnection structures 390 can be connected to conductive layer 380, whereas the second ends of bit line interconnection structures 390 can be connected to the bit lines 360. In some implementations, a fifth distance D5 between adjacent bit line interconnection structures 390 in the same row is in a range between about 60 nm and about 120 nm, such as approximately 90 nm. Such pitch distance can meet the overlay requirement for routing in BEOL metal layer 380.

In some implementations, adjacent bit lines 360 can be separated from each other by a spacer layer 330 including an insulating layer 370 and one or more air gaps. The insulating layer 370 can include any suitable dielectric materials including, but not limited to, silicon oxide, silicon nitride, silicon oxynitride, low-k dielectrics, or any combination thereof. The one or more air gaps may be formed due to the relatively small pitches between adjacent bit lines 360. Further, the relatively large dielectric constant of air in air gaps (e.g., about four times the dielectric constant of silicon oxide) can improve the insulation effect between adjacent bit lines 360. In some implementations, insulating layer 370 is further located between bit lines 360 and conductive layer 380. Bit line interconnection structures 390 vertically extend through insulating layer 370 to connect bit lines 360 to conductive layer 380.

In some implementations, bit line interconnection structures 390 can extend into bit lines 360 to increase the contact area for better contact conductivity. Bit line interconnection structures 390 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. In some implementations, bit line interconnection structures 390 can include multiple conductive layers, such as a W layer over a TiN layer.

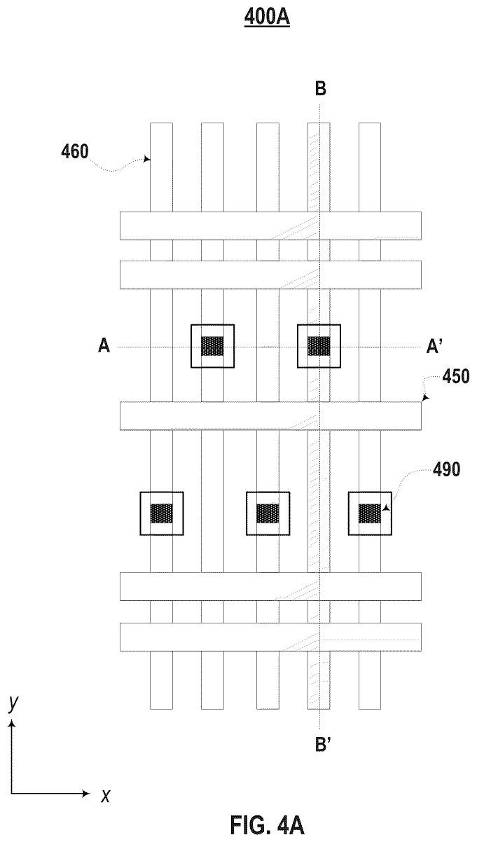

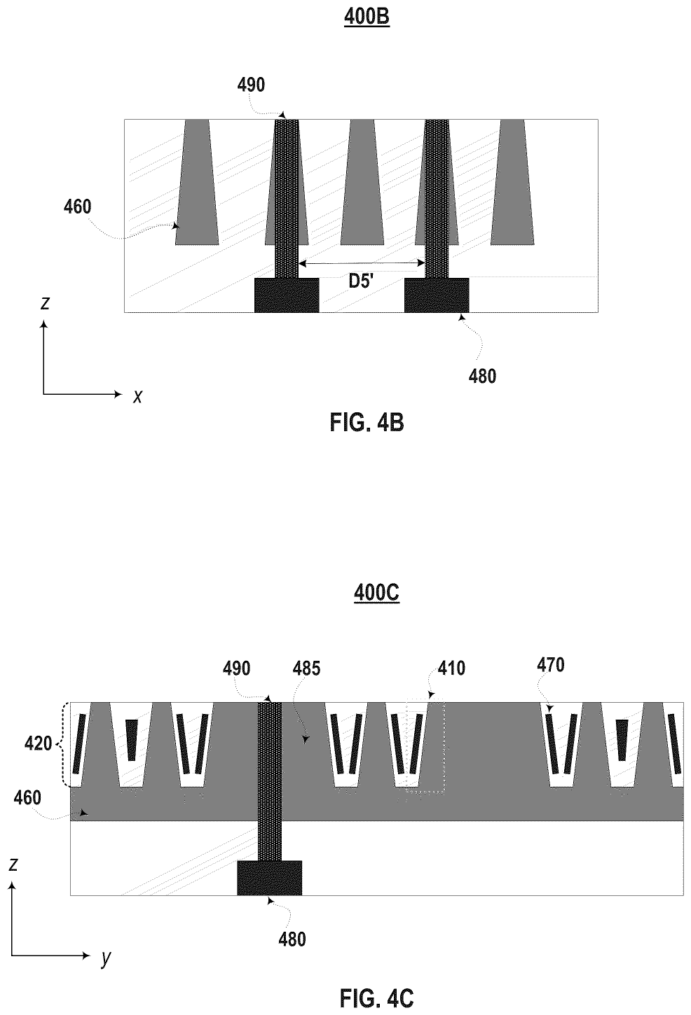

FIG. 4A illustrates a schematic plan view of a memory array 400A in the x-y plane, according to some implementations of the present disclosure. As shown in FIG. 4A, a plurality of word lines 450 extend in parallel along the first lateral direction (the x-direction), and a plurality of bit lines 460 extend in parallel along the second lateral direction (the y-direction). The word lines 450 and bit lines 460 may be formed in different lateral planes for ease of routing. In some implementations, memory array 400A further comprises a plurality of bit line interconnection structures 490 located within the array region and coupled with the bit lines 460, and arranged in staggered rows along the first lateral direction (the x-direction). The bit lines 460 can be interconnected to the corresponding bit line interconnection structures 490 in a staggered manner.

In some implementations, a first row of bit line interconnection structures 490 aligned along the first lateral direction can be connected to the even numbers of bit lines 460, respectively, while a second row of bit line interconnection structures 490 aligned along the first lateral direction can be connected to the odd numbers of bit lines 460, respectively. As shown in FIG. 4A, the first row of bit line interconnection structures 490 can be located at a first side of one word line 450 of the array region of memory array 400A, and the second row of bit line interconnection structures 490 can be located at a second side of the word line 450 of the array region of memory array 400A opposite to the first side.

FIG. 4B illustrates a schematic side cross-sectional view 400B in the x-z plane of memory array 400A shown along AA′ line, according to some implementations of the present disclosure. FIG. 4C illustrates a schematic side cross-sectional view 400C in the y-z plane of memory array 400A shown along BB′ line, according to some implementations of the present disclosure. As shown in FIGS. 4B and 4C, a row of bit line interconnection structures 490 along the first lateral direction (the x-direction) can be alternatively connected between corresponding even/odd number bit lines 460 and BEOL metal layer 480. In some implementations, as shown in FIG. 4B, a fifth distance D5′ between adjacent bit line interconnection structures 490 in the same row is in a range between about 60 nm and about 120 nm, such as approximately 90 nm. Such pitch distance can meet the overlay requirement for routing in BEOL metal layer 480.

As shown in FIG. 4C, a transistor layer 420 includes a plurality of vertical transistors 410 having a semiconductor layer 485 and a gate electrode 470 at one or more lateral sides of semiconductor layer 485. In some implementations, bit line 460 is in contact with lower ends of semiconductor layer 485. In some implementations, bit line interconnection structure 490 can extend through bit line 460 and into semiconductor layer 485 of transistor layer 420. Gate electrode 470 can be located at one or more lateral sides of semiconductor layer 485 to form CAA type, SMG type, DMG type, or TMG type vertical transistor 410. In some implementations, gate electrodes 470 of a row of vertical transistors 410 along the first lateral direction (the x-direction) can be connected with each other to form word line 450.

Gate electrode 470 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 470 may include doped polysilicon, i.e., gate poly. In some implementations, gate electrode 470 includes multiple conductive layers, such as a W layer over a TiN layer. In some implementations, a gate dielectric layer can be located between the semiconductor layer 480 and the gate electrode 470. The gate dielectric layer can include any suitable dielectric materials, such as silicon oxide, silicon nitride, silicon oxynitride, or high-k dielectrics.

In some implementations, bit line interconnection structures 490 can extend into bit lines 460 to increase the contact area for better contact conductivity. Bit line interconnection structures 490 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. In some implementations, bit line interconnection structures 490 can include multiple conductive layers, such as a W layer over a TiN layer.

In some implementations but not shown in the figures, each memory cell of the memory array 300A/400A in the disclosed memory device can further include a storage unit coupled with the vertical transistor 410. The storage unit can include any devices that can store binary data (e.g., 0 and 1), including but not limited to, capacitors for DRAM cells, and PCM elements for PCM cells. In some implementations, each vertical transistor controls the selection and/or the state switch of the respective storage unit coupled to the vertical transistor 410. In some implementations, the storage unit includes a capacitor. It is understood that the capacitor may include any suitable structure and configuration, such as a planar capacitor, a stack capacitor, a multi-fins capacitor, a cylinder capacitor, a trench capacitor, or a substrate-plate capacitor.

In some implementations, one or more peripheral circuits (not shown) can be coupled to the memory cell array 300A/400A through bit lines 360/460, word lines 450, and any other suitable metal wirings. It is noted that the one or more peripheral circuits can include any suitable circuits for facilitating the operations of memory cell array 300A/400A by applying and sensing voltage signals and/or current signals through word lines 450 and bit lines 360/460 to and from each vertical transistor 410. The one or more peripheral circuits can include various types of peripheral circuits formed using CMOS technologies.

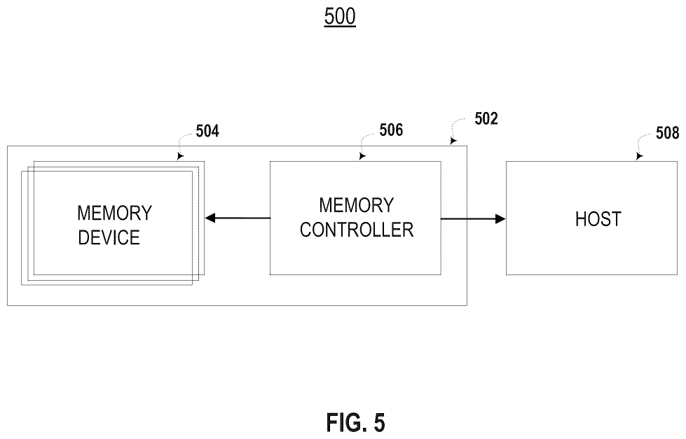

FIG. 5 illustrates a block diagram of a system 500 having a memory device, according to some implementations of the present disclosure. System 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, system 500 can include a host 508 and a memory system 502 having one or more memory devices 504 and a memory controller 506. Host 508 can be a processor of an electronic device, such as a central processing unit (CPU), or a system-on-chip (SoC), such as an application processor (AP). Host 508 can be configured to send or receive the data to or from memory devices 504. Memory device 504 can be any memory devices disclosed herein, such as memory device 100. In some implementations, memory device 504 includes one or more arrays of memory cells shown in 200A/200B/300A/400A, as described above in detail.

Memory controller 506 is coupled to memory device 504 and host 508 and is configured to control memory device 504, according to some implementations. Memory controller 506 can manage the data stored in memory device 504 and communicate with host 508. Memory controller 506 can be configured to control operations of memory device 504, such as read, write, and refresh operations. Memory controller 506 can also be configured to manage various functions with respect to the data stored or to be stored in memory device 504 including, but not limited to refresh and timing control, command/request translation, buffer and schedule, and power management. In some implementations, memory controller 506 is further configured to determine the maximum memory capacity that the computer system can use, the number of memory banks, memory type and speed, memory particle data depth and data width, and other important parameters. Any other suitable functions may be performed by memory controller 506 as well. Memory controller 506 can communicate with an external device (e.g., host 508) according to a particular communication protocol. For example, memory controller 506 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

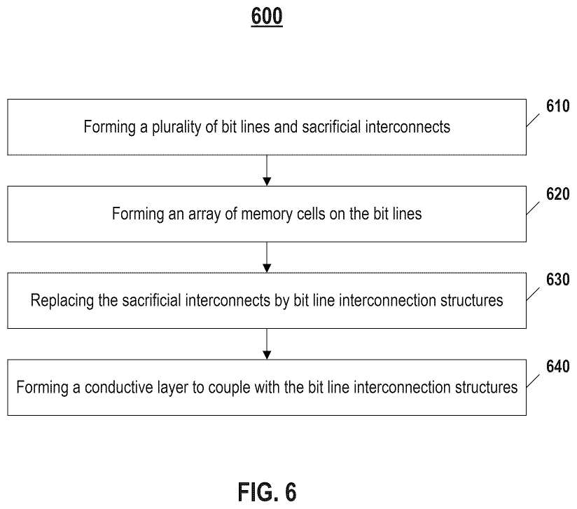

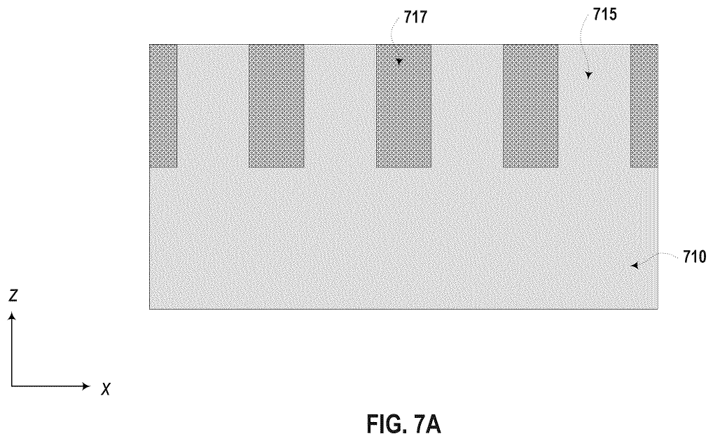

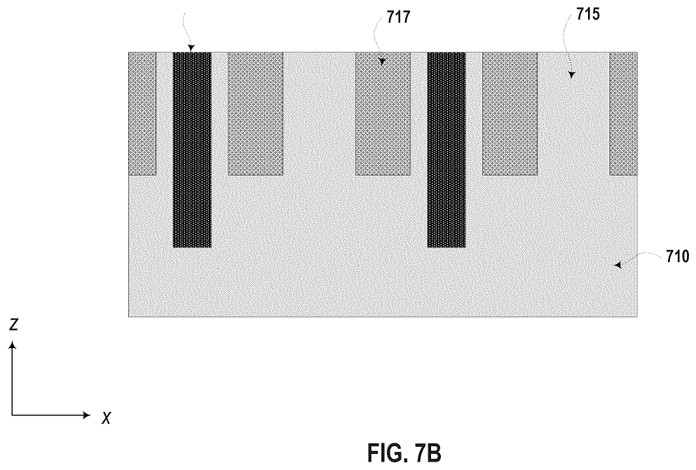

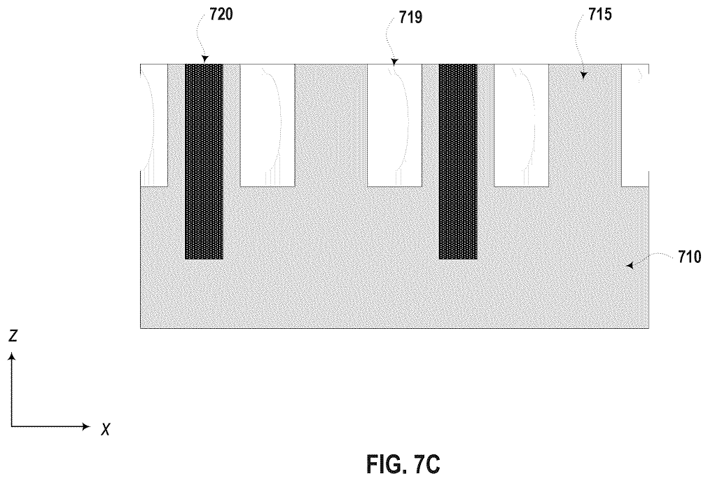

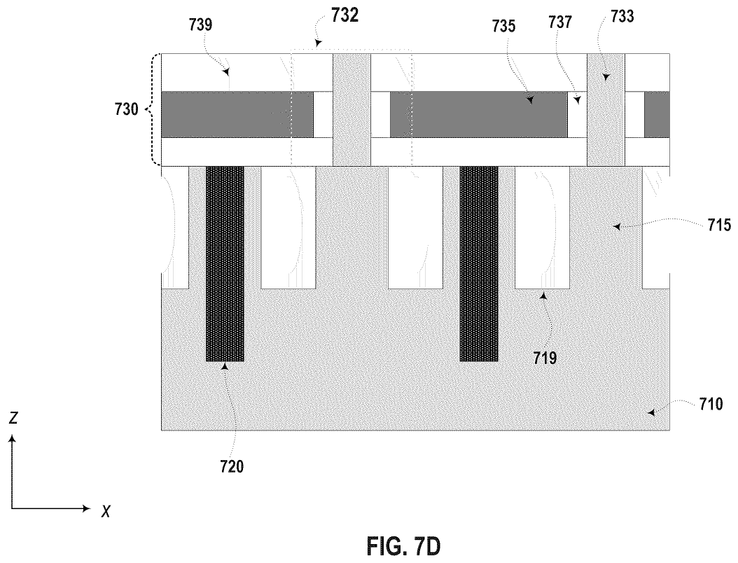

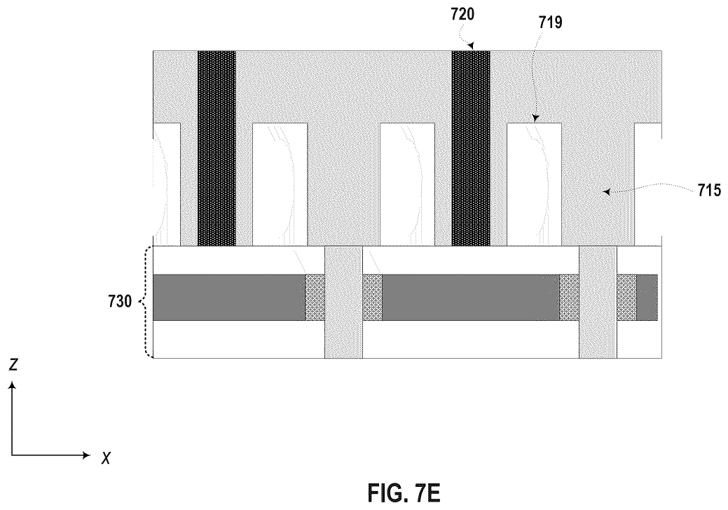

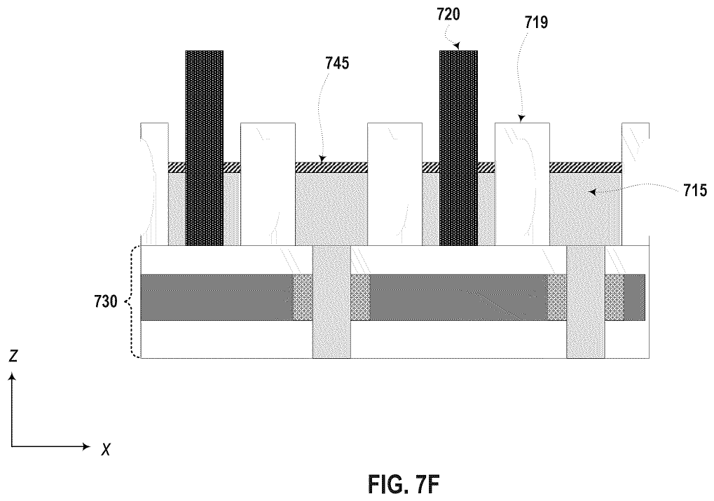

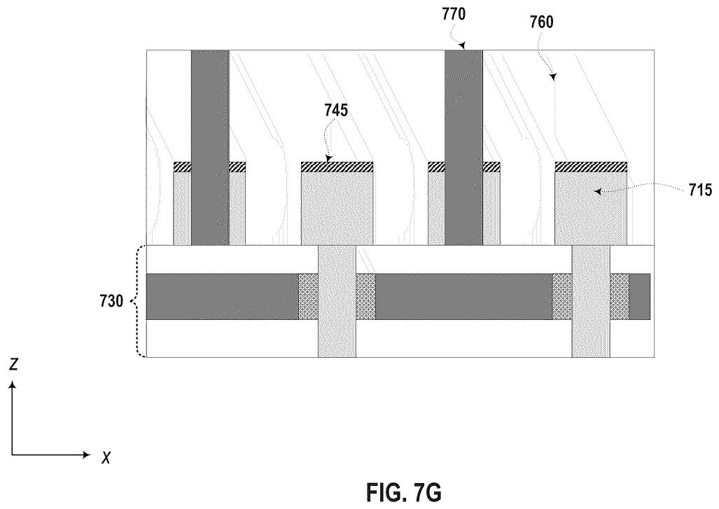

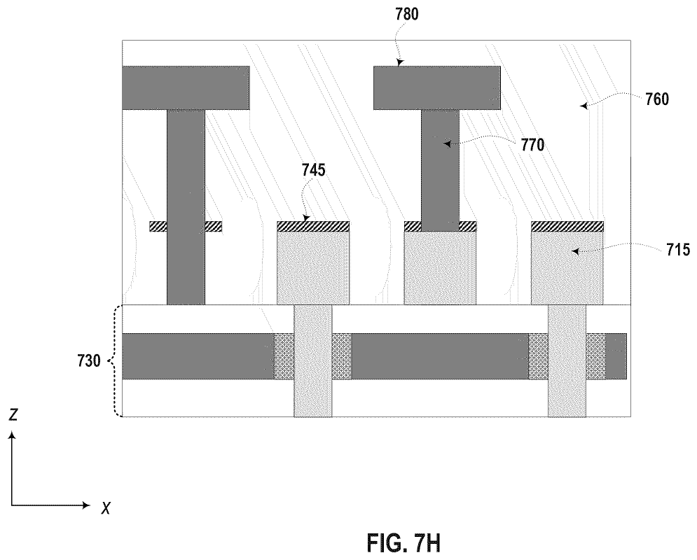

FIG. 6 illustrates a flowchart of a fabricating method 600 for forming a 3D memory device, according to some implementations of the present disclosure. FIGS. 7A-7H illustrate schematic side cross-sectional views of a 3D memory device at certain fabricating stages of the method 600 shown in FIG. 6, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, method 600 can start at operation 610, in which a plurality of bit lines and sacrificial interconnects can be formed. FIGS. 7A-7C each illustrates a schematic side cross-sectional view of the 3D memory device in the x-z plane at a certain stage of operation 610 of method 600.

As shown in FIG. 7A, a plurality of bit lines 715 can be formed on a substrate 710. In some implementations, substrate 710 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In such implementations, the plurality of bit lines 715 can be formed by a patterning process (e.g., photoetching, dry etching, wet etching, cleaning, chemical mechanical polishing (CMP), etc., to remove portions of substrate 710 to form parallel trenches each extending in the second lateral direction (the y-direction). The trenches can then be filled with sacrificial material in a deposition process to form temporary spacers 717. The protruding portions of substrate 710 laterally separated by temporary spacers 717 can form the plurality of bit lines 715, parallelly arranged in the first lateral direction (the x-direction), each extending along the second lateral direction (the y-direction).

As shown in FIG. 7B, a plurality of sacrificial interconnects 720 can be formed to penetrate bit lines 715 and to extend into substrate 710. In some implementations, the plurality of sacrificial interconnects 720 can be formed by removing portions of bit lines 715 and substrate 710 to form openings each vertically extending through bit lines 715 into substrate 710, and filling the openings with a sacrificial material. In some implementations, the plurality of sacrificial interconnects 720 can be formed in the array region, and be arranged in staggered rows along the first lateral direction (the x-direction). In some implementations, a first row of sacrificial interconnects 720 aligned along the first lateral direction can be connected to the even numbers of bit lines 715, respectively, while a second row of sacrificial interconnects 720 aligned along the first lateral direction can be connected to the odd numbers of bit lines 715, respectively.

As shown in FIG. 7B, temporary spacers 717 can be replaced by insulating layer 719 with one or more air gaps. In some implementations, the sacrificial material of temporary spacers 717 can be removed by any suitable process, such as wet etching, to recreate the parallel trenches. The parallel trenches can then be filled with any suitable dielectric material in a deposition process to form insulating layer 719 with one or more air gaps. The insulating layer 719 can include any suitable dielectric materials including, but not limited to, silicon oxide, silicon nitride, silicon oxynitride, low-k dielectrics, or any combination thereof.

Referring back to FIG. 6, method 600 can proceed to operation 620, in which an array of memory cells can be formed on the bit lines. FIG. 7D illustrates a schematic side cross-sectional view of the 3D memory device in the x-z plane after operation 620 of method 600.

As shown in FIG. 7D, forming the array of memory cells can include forming a transistor layer 730 comprising an array of vertical transistors 732. Forming the transistor layer 730 can include forming a plurality of vertical semiconductor pillars 733 each penetrating an insulating layer 739. Each column of vertical semiconductor pillars 733 along the second lateral direction (the y-direction) can be in contact with a corresponding same bit line 715. In some implementations, vertical semiconductor pillars 733 can include any suitable semiconductor material, such as polycrystalline silicon. Vertical semiconductor pillars 733 can have a leakage value lower than a pico-ampere. In some implementations, the leakage value of vertical semiconductor pillars 733 is lower than the intrinsic leakage value of monocrystalline silicon. In some implementations, a material of vertical semiconductor pillars 733 can be a metal oxide semiconductor material, such as IGZO.

As shown in FIG. 7D, forming transistor layer 730 can further include forming gate electrodes 735 at one or more lateral sides of vertical semiconductor pillars 733, and forming gate dielectric layer 737 between gate electrodes 735 and vertical semiconductor pillars 733. In some implementations, gate electrodes 735 of each row of vertical transistors 732 along the first lateral direction (x-direction) can be connected with each other to form one word line. Gate electrodes 735 can include any suitable conductive materials, such as polysilicon, metals (e.g., W, Cu, Al, etc.), metal compounds (e.g., TiN, TaN, etc.), or silicides. For example, gate electrode 735 may include doped polysilicon, i.e., gate poly. In some implementations, gate electrode 735 includes multiple conductive layers, such as a W layer over a TiN layer. Gate dielectric layer 737 can include any suitable dielectric materials, such as silicon oxide, silicon nitride, silicon oxynitride, or high-k dielectrics. For example, gate dielectric layer 737 may include silicon oxide, i.e., gate oxide. In some implementations, gate electrodes 735 and gate dielectric layer 737 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc.).

Although not shown in FIG. 7D, forming the array of memory cells can further include forming a storage unit layer including an array of storage units each coupled with a corresponding one of the array of vertical transistors 732. In some implementations, the array of storage units can be an array of capacitors including a common second electrode, a plurality of first electrode, and a capacitor dielectric layer between the first electrodes and the common second electrode. In some implementations, the first electrodes and/or the common second electrode can include conductive materials including, but not limited to, W, Co, Cu, Al, TiN, TaN, polysilicon, silicides, or any combination thereof. In some implementations, the capacitor dielectric layer includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the array of capacitors can be formed by a series of fabricating processes including thin film deposition processes (e.g., CVD, PVD, ALD, etc.) and patterning processes (e.g., photoetching, dry etching, wet etching, cleaning, CMP, etc.).

Referring back to FIG. 6, method 600 can proceed to operation 630, in which the sacrificial interconnects can be replaced by bit line interconnection structures. FIGS. 7E-7G each illustrates a schematic side cross-sectional view of the 3D memory device in the x-z plane at a certain stage of operation 630 of method 600.

In some implementations, the 3D structure shown in FIG. 7D can be flipped over. Portions of substrate 710 can be removed by any suitable process, such as dry etching, wet etching, CMP, etc., to expose the plurality of sacrificial interconnects 720, as shown in FIG. 7E. As shown in FIG. 7F, portions of substrate 710 can be further removed by any suitable process, such as dry etching, wet etching, CMP, etc., to expose portions of the insulating layer 719 and bit lines 715. A protection layer 745 can be formed to cover exposed surfaces of bit lines 715. In some implementations, protection layer 745 can include any suitable dielectric material having an etching ratio different from that of the material of sacrificial interconnects 720 during one or more selective etching processes. For example, protection layer 745 can include a silicide material. In some implementations, protection layer 745 can be formed by oxidizing the exposed surfaces of bit lines 715.

As shown in FIG. 7G, the plurality of sacrificial interconnects 720 can be removed by any suitable etching process, such as a wet etching process. Protection layer 745 can protect bit lines 715 during the etching process for removing sacrificial interconnects 720. A conductive material can then be deposited to form bit line interconnection structures 770, and an insulating layer 760 can be formed to cover protection layer 745 and sidewalls of bit line interconnection structures 770. In some implementations, bit line interconnection structures 770 can include any suitable conductive materials, such as polysilicon, metals (e.g., W, Cu, Al, etc.), metal compounds (e.g., TiN, TaN, etc.), or silicides. In some implementations, bit line interconnection structures 770 can include multiple conductive layers, such as a W layer over a TiN layer. The insulating layer 760 can include any suitable dielectric materials including, but not limited to, silicon oxide, silicon nitride, silicon oxynitride, low-k dielectrics, or any combination thereof.

Referring back to FIG. 6, method 600 can proceed to operation 640, in which a conductive layer can be formed to couple with the bit line interconnection structures. FIG. 7H illustrates a schematic side cross-sectional view of the 3D memory device in the x-z plane after operation 640 of method 600.

As shown in FIG. 7H, a conductive layer 780 can be formed in insulating layer 760 and in contact with bit line interconnection structures 770. In some implementations, conductive layer 780 can include one or more BEOL metal layers, and can be formed by any suitable series of fabricating processes including thin film deposition processes (e.g., CVD, PVD, ALD, etc.) and patterning processes (e.g., photoetching, dry etching, wet etching, cleaning, CMP, etc.).

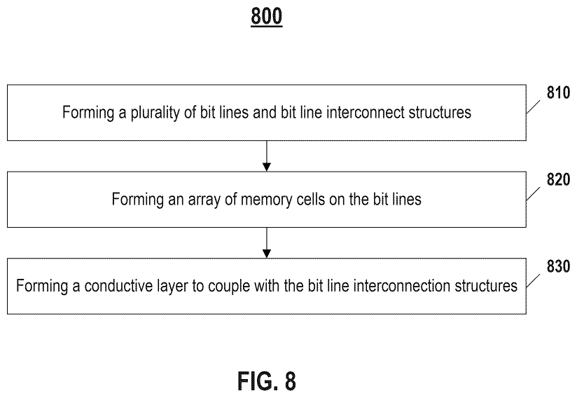

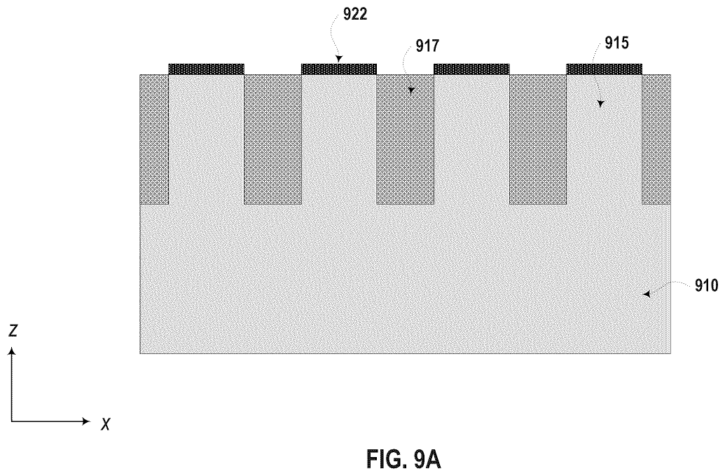

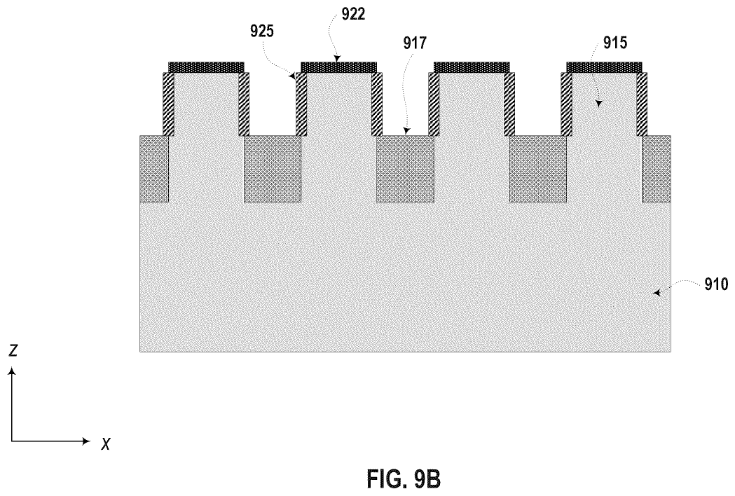

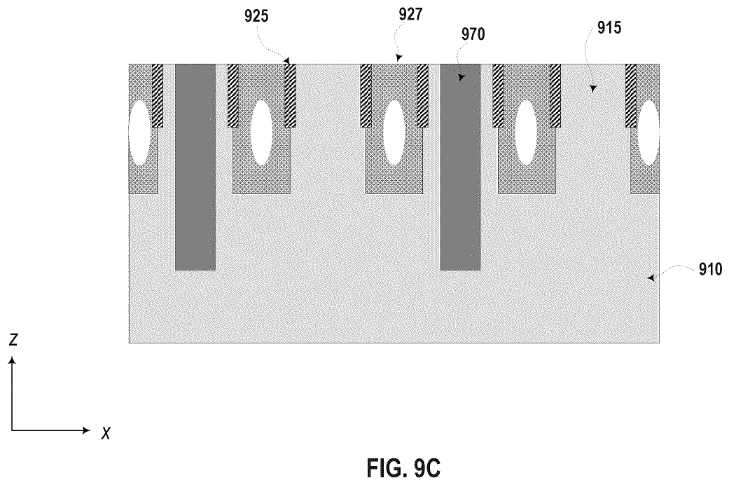

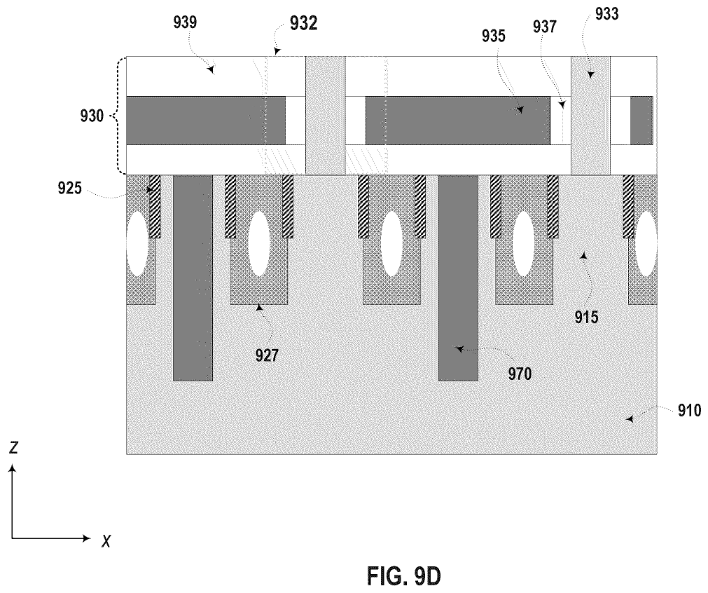

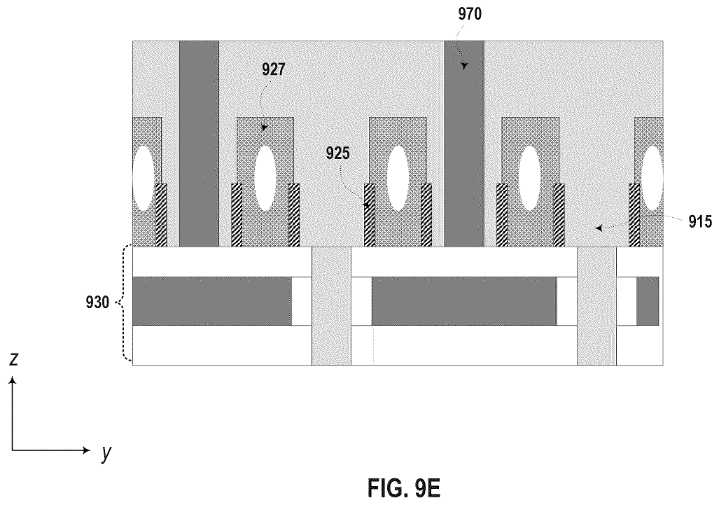

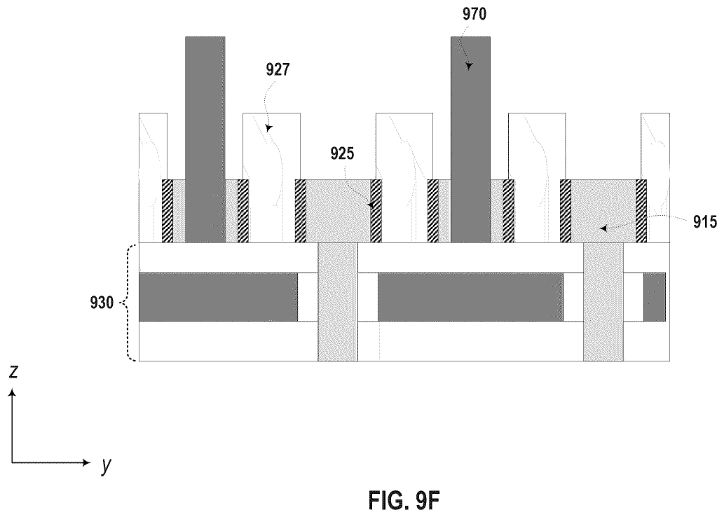

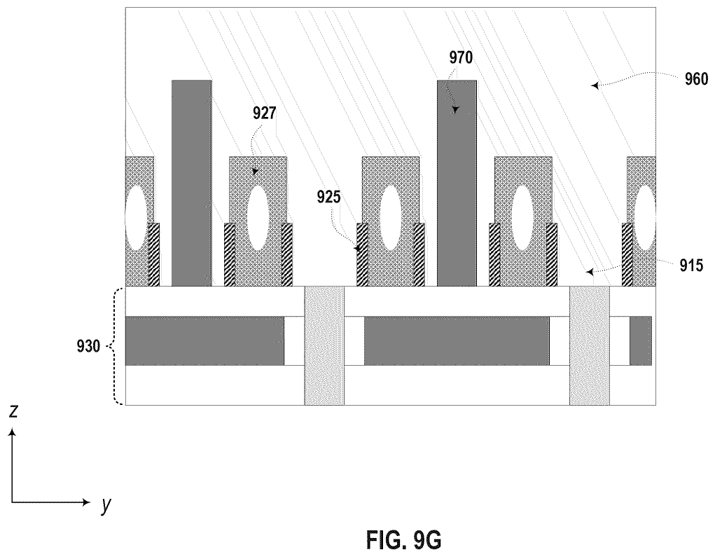

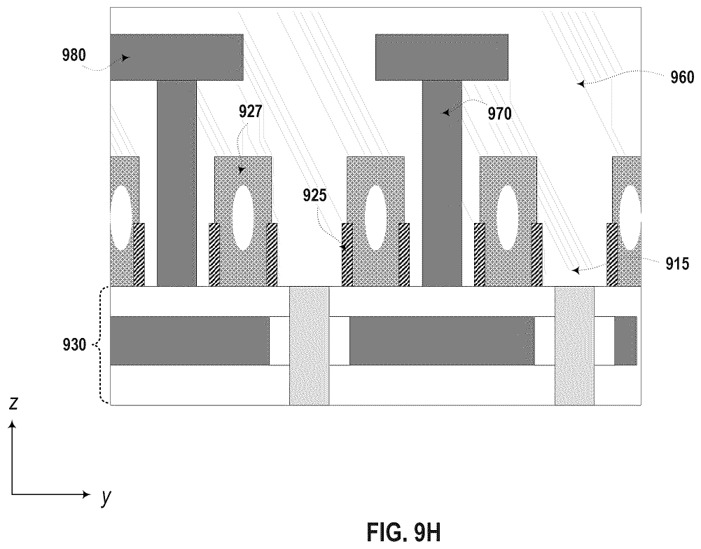

FIG. 8 illustrates a flowchart of a fabricating method 800 for forming a 3D memory device, according to some implementations of the present disclosure. FIGS. 9A-9H illustrate schematic side cross-sectional views of a 3D memory device at certain fabricating stages of the method 800 shown in FIG. 8, according to various implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIG. 8, method 800 can start at operation 810, in which a plurality of bit lines and bit line interconnect structures can be formed. FIGS. 9A-9C each illustrates a schematic side cross-sectional view of the 3D memory device in an x-z plane at a certain stage of operation 810 of method 800.

As shown in FIG. 9A, a plurality of bit lines 915 can be formed on a substrate 910. In some implementations, substrate 910 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In such implementations, the plurality of bit lines 915 can be formed by a patterning process (e.g., photoetching, dry etching, wet etching, cleaning, chemical mechanical polishing (CMP), etc., to remove portions of substrate 910 to form parallel trenches each extending in the second lateral direction (the y-direction). The trenches can then be filled with sacrificial material in a deposition process to form temporary spacers 917. The protruding portions of substrate 910 laterally separated by temporary spacers 917 can form the plurality of bit lines 915, parallelly arranged in the first lateral direction (the x-direction), each extending along the second lateral direction (the y-direction).

In some implementations, a mask layer 922 can be formed to cover the exposed top surfaces of the plurality of bit lines 915, as shown in FIG. 9B. Mask layer 922 can include any suitable high-k dielectrics, such as a nitride material. As shown in FIG. 9C, using the mask layer 922 to protect the plurality of bit lines 915, an etching process, such as a dry etching or a wet etching, can be performed to remove portions of the temporary spacers 917 to expose the sidewalls of the plurality of bit lines 915. In some implementations, protection layers 925 can be formed on the sidewalls of the plurality of bit lines 915 to protect the plurality of bit lines 915 in the subsequent processes. For example, an oxidization process can be performed to oxidize the exposed surfaces of the sidewalls of the plurality of bit lines 915 to form silicide layers as protection layers 925.

As shown in FIG. 9C, a plurality of bit line interconnect structures 970 can be formed to penetrate bit lines 915 and to extend into substrate 910. In some implementations, the plurality of bit line interconnect structures 970 can be formed by removing portions of bit lines 915 and substrate 910 to form openings each vertically extending through bit lines 715 into substrate 910, and filling the openings with a conductive material. In some implementations, the plurality of bit line interconnect structures 970 can be formed in the array region, and be arranged in staggered rows along the first lateral direction (the x-direction). In some implementations, a first row of bit line interconnect structures 970 aligned along the first lateral direction can be connected to the even numbers of bit lines 915, respectively, while a second row of bit line interconnect structures 970 aligned along the first lateral direction can be connected to the odd numbers of bit lines 915, respectively. In some implementations, bit line interconnection structures 970 can include any suitable conductive materials, such as polysilicon, metals (e.g., W, Cu, Al, etc.), metal compounds (e.g., TiN, TaN, etc.), or silicides. In some implementations, bit line interconnection structures 970 can include multiple conductive layers, such as a W layer over a TiN layer.

As shown in FIG. 7C, temporary spacers 917 can be replaced by insulating layer 927 with one or more air gaps. In some implementations, the sacrificial material of temporary spacers 917 can be removed by any suitable process, such as wet etching, to recreate the parallel trenches. The parallel trenches can then be filled with any suitable dielectric material in a deposition process to form insulating layer 927 with one or more air gaps. The insulating layer 927 can include any suitable dielectric materials including, but not limited to, silicon oxide, silicon nitride, silicon oxynitride, low-k dielectrics, or any combination thereof.

Referring back to FIG. 8, method 800 can proceed to operation 820, in which an array of memory cells can be formed on the bit lines. FIG. 9D illustrates a schematic side cross-sectional view of the 3D memory device in the x-z plane after operation 820 of method 800.

As shown in FIG. 9D, forming the array of memory cells can include forming a transistor layer 930 comprising an array of vertical transistors 932. Forming the transistor layer 930 can include forming a plurality of vertical semiconductor pillars 933 each penetrating an insulating layer 939. Each column of vertical semiconductor pillars 933 along the second lateral direction (the y-direction) can be in contact with a corresponding same bit line 915. In some implementations, vertical semiconductor pillars 933 can include any suitable semiconductor material, such as polycrystalline silicon. Vertical semiconductor pillars 933 can have a leakage value lower than a pico-ampere. In some implementations, the leakage value of vertical semiconductor pillars 933 is lower than the intrinsic leakage value of monocrystalline silicon. In some implementations, a material of vertical semiconductor pillars 933 can be a metal oxide semiconductor material, such as IGZO.

As shown in FIG. 9D, forming transistor layer 930 can further include forming gate electrodes 935 at one or more lateral sides of vertical semiconductor pillars 933, and forming gate dielectric layer 937 between gate electrodes 935 and vertical semiconductor pillars 933. In some implementations, gate electrodes 935 of each row of vertical transistors 932 along the first lateral direction (x-direction) can be connected with each other to form one word line. Gate electrodes 935 can include any suitable conductive materials, such as polysilicon, metals (e.g., W, Cu, Al, etc.), metal compounds (e.g., TiN, TaN, etc.), or silicides. For example, gate electrode 935 may include doped polysilicon, i.e., gate poly. In some implementations, gate electrode 935 includes multiple conductive layers, such as a W layer over a TiN layer. Gate dielectric layer 937 can include any suitable dielectric materials, such as silicon oxide, silicon nitride, silicon oxynitride, or high-k dielectrics. For example, gate dielectric layer 937 may include silicon oxide, i.e., gate oxide. In some implementations, gate electrodes 935 and gate dielectric layer 937 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc.).

Although not shown in FIG. 9D, forming the array of memory cells can further include forming a storage unit layer including an array of storage units each coupled with a corresponding one of the array of vertical transistors 932. In some implementations, the array of storage units can be an array of capacitors including a common second electrode, a plurality of first electrode, and a capacitor dielectric layer between the first electrodes and the common second electrode. In some implementations, the first electrodes and/or the common second electrode can include conductive materials including, but not limited to, W, Co, Cu, Al, TIN, TaN, polysilicon, silicides, or any combination thereof. In some implementations, the capacitor dielectric layer includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the array of capacitors can be formed by a series of fabricating processes including thin film deposition processes (e.g., CVD, PVD, ALD, etc.) and patterning processes (e.g., photoetching, dry etching, wet etching, cleaning, CMP, etc.).

Referring back to FIG. 8, method 800 can proceed to operation 830, in which a conductive layer can be formed to couple with the bit line interconnection structures. FIGS. 9E-9H each illustrates a schematic side cross-sectional view of the 3D memory device in the x-z plane at a certain stage of operation 830 of method 800.

In some implementations, the 3D structure shown in FIG. 9D can be flipped over. Portions of substrate 910 can be removed by any suitable process, such as dry etching, wet etching, CMP, etc., to expose the plurality of bit line interconnection structures 970, as shown in FIG. 9E. As shown in FIG. 9F, portions of substrate 910 can be further removed by any suitable process, such as dry etching, wet etching, CMP, etc., to expose portions of protection layer 925 and bit lines 915. As shown in FIG. 9G, an insulating layer 960 can be formed to cover protection layer 925 and bit lines 915. As shown in FIG. 9H, a conductive layer 980 can be formed in insulating layer 960 and in contact with bit line interconnection structures 970. In some implementations, conductive layer 980 can include one or more BEOL metal layers, and can be formed by any suitable series of fabricating processes including thin film deposition processes (e.g., CVD, PVD, ALD, etc.) and patterning processes (e.g., photoetching, dry etching, wet etching, cleaning, CMP, etc.).

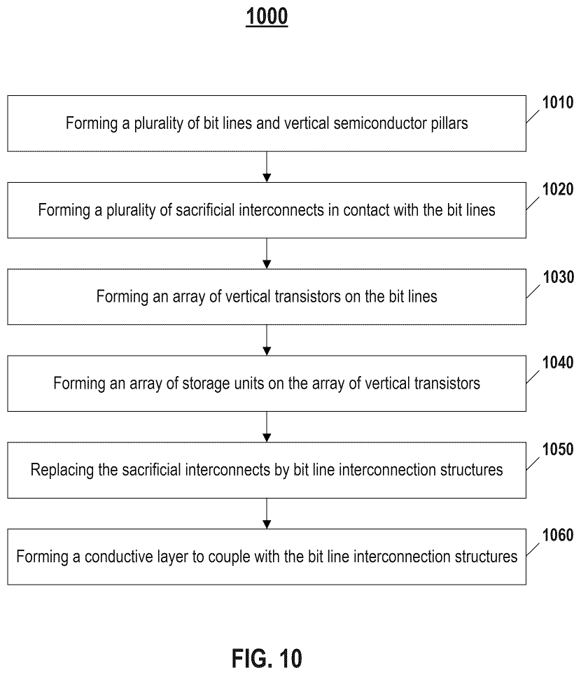

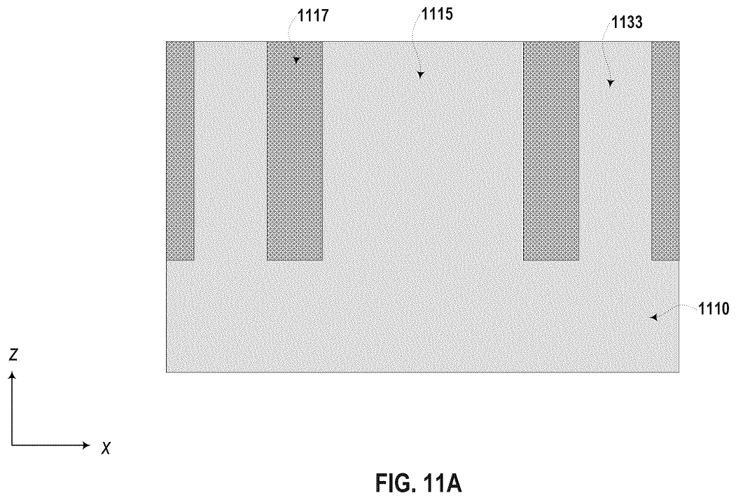

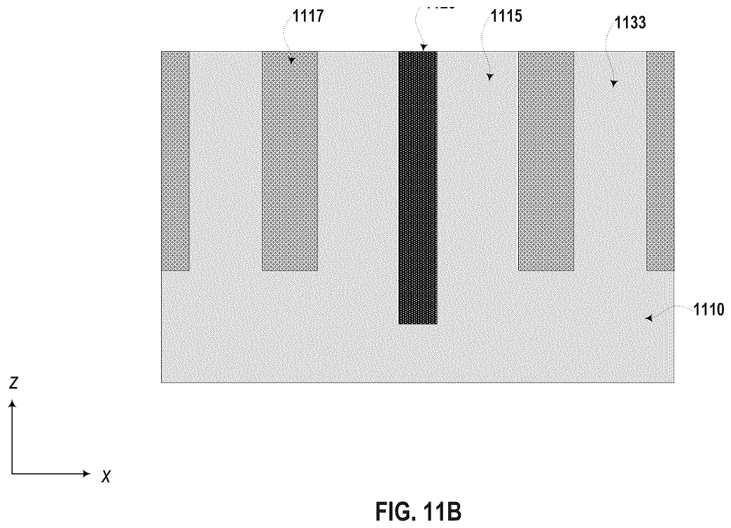

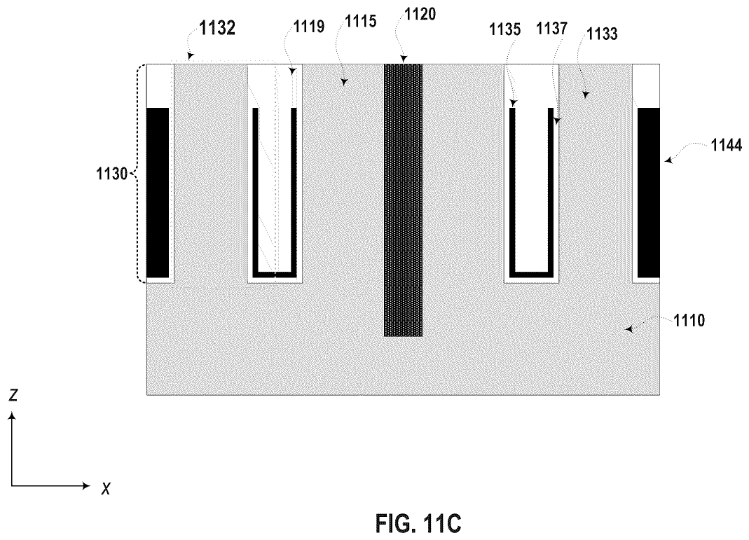

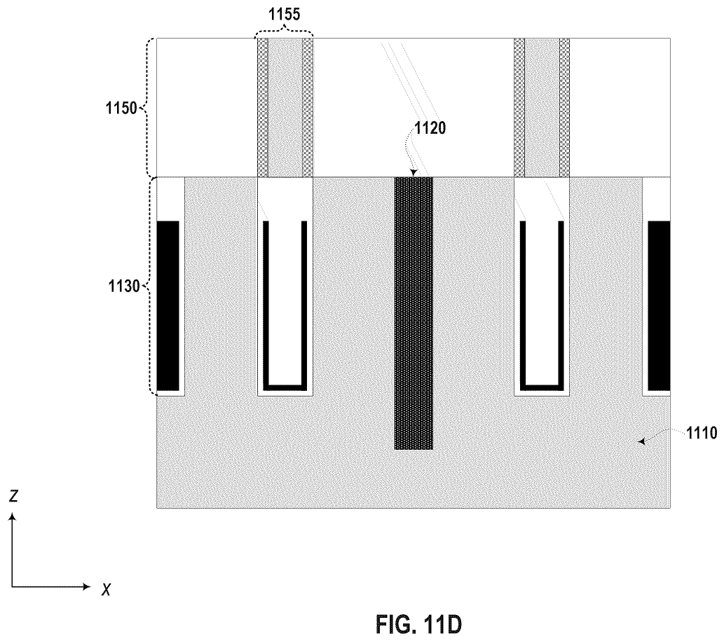

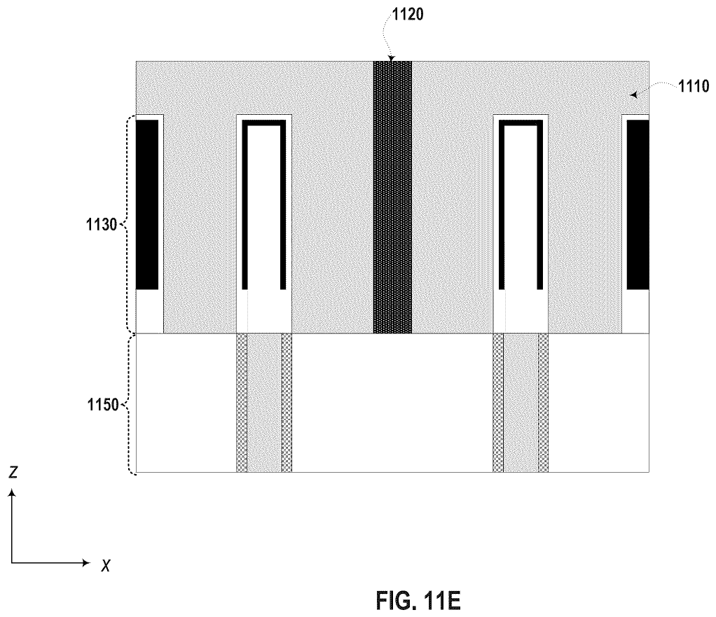

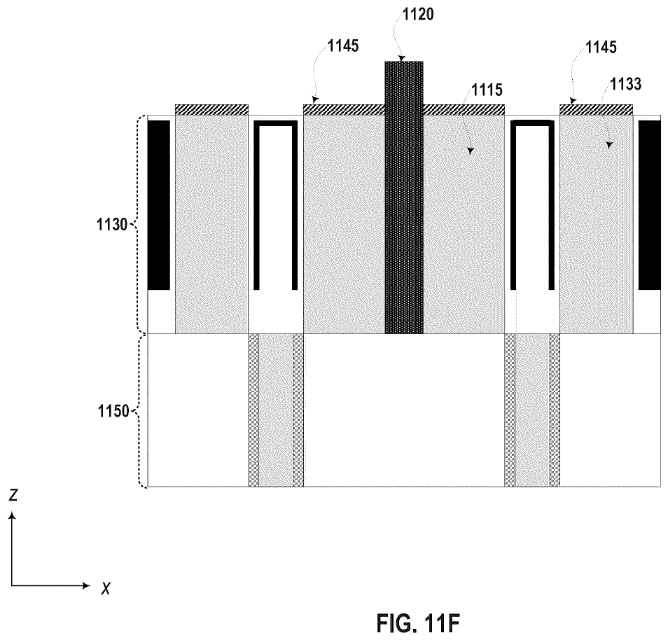

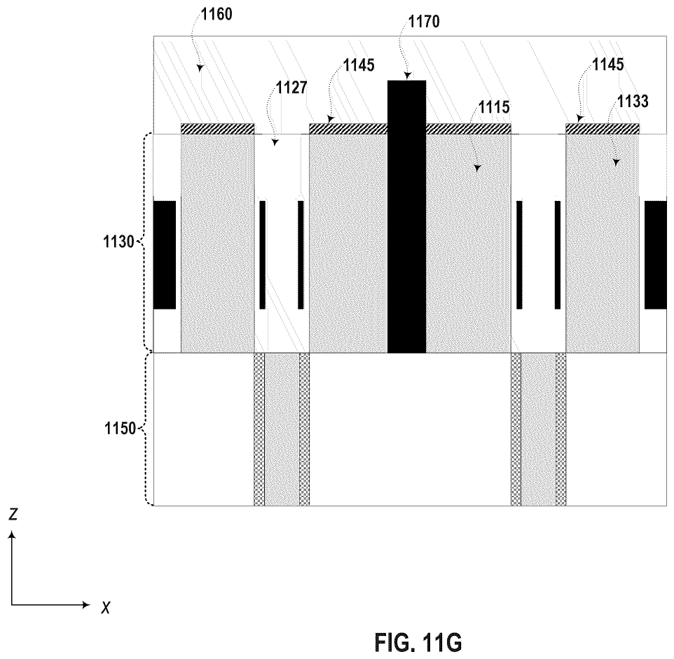

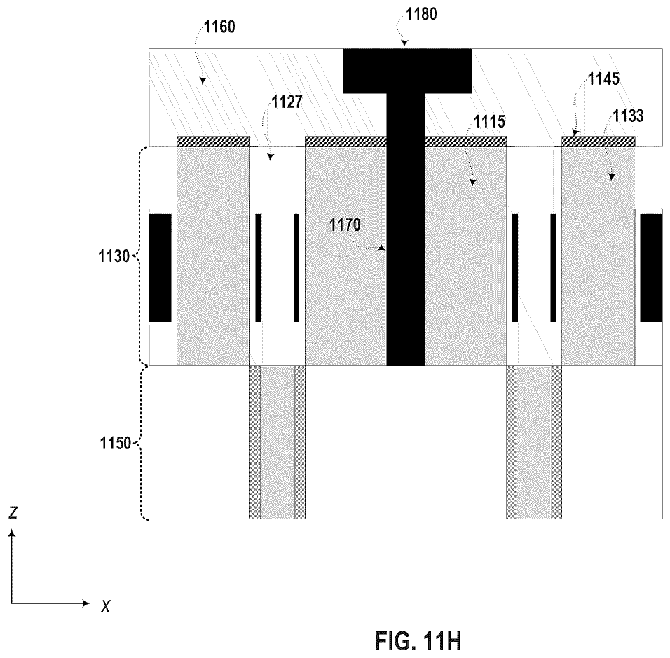

FIG. 10 illustrates a flowchart of a fabricating method 1000 for forming a 3D memory device, according to some implementations of the present disclosure. FIGS. 11A-11H illustrate schematic side cross-sectional views of a 3D memory device at certain fabricating stages of the method 1000 shown in FIG. 10, according to various implementations of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10.

As shown in FIG. 10, method 1000 can start at operation 1010, in which a plurality of bit lines and vertical semiconductor pillars can be formed. FIG. 11A illustrates a schematic side cross-sectional view of the 3D memory device in x-z plane after operation 1010 of method 1000.

As shown in FIG. 11A, a plurality of bit lines 1115 and a plurality of vertical semiconductor pillars 1133 can be formed on a substrate 1110. In some implementations, the plurality of bit lines 1115 can be arranged in parallel each extending in the second lateral direction (the y-direction). In some implementations, the vertical semiconductor pillars 1133 can be arranged in an array in the lateral plane. In some implementations, substrate 1110 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some implementations, bit lines 1115 and vertical semiconductor pillars 733 can include the same material as substrate 1110.

In such implementations, the plurality of bit lines 1115 and the plurality of vertical semiconductor pillars 1133 can be formed by a patterning process (e.g., photoetching, dry etching, wet etching, cleaning, chemical mechanical polishing (CMP), etc., to remove portions of substrate 1110 to form trenches each extending in the first lateral direction (the x-direction) and the second lateral direction (the y-direction). The trenches can then be filled with sacrificial material in a deposition process to form temporary spacers 1117. The protruding portions of substrate 1110 laterally separated by temporary spacers 1117 can form the plurality of bit lines 1115 and the plurality of vertical semiconductor pillars 1133.

As shown in FIG. 10, method 1000 can proceed to operation 1020, in which a plurality of sacrificial interconnects can be formed in contact with the bit lines. FIG. 11B illustrates a schematic side cross-sectional view of the 3D memory device in x-z plane after operation 1020 of method 600.

As shown in FIG. 11B, a plurality of sacrificial interconnects 1120 can be formed to penetrate bit lines 1115 and to extend into substrate 1110. In some implementations, the plurality of sacrificial interconnects 1120 can be formed by removing portions of bit lines 715 and substrate 1110 to form openings each vertically extending through bit lines 1115 into substrate 1110. The openings can then be filled with a sacrificial material to form sacrificial interconnects 1120. In some implementations, the plurality of sacrificial interconnects 1120 can be formed in the array region, and be arranged in staggered rows along the first lateral direction (the x-direction). In some implementations, a first row of sacrificial interconnects 1120 aligned along the first lateral direction can be connected to the even numbers of bit lines 1115, respectively, while a second row of sacrificial interconnects 1120 aligned along the first lateral direction can be connected to the odd numbers of bit lines 1115, respectively.

Referring back to FIG. 10, method 1000 can proceed to operation 1030, in which an array of vertical transistors can be formed on the bit lines. FIG. 11C illustrates a schematic side cross-sectional view of the 3D memory device in the x-z plane after operation 1030 of method 1000.

As shown in FIG. 11C, temporary spacers 1117 can be replaced by insulating layer 1119. In some implementations, the sacrificial material of temporary spacers 1117 can be removed by any suitable process, such as wet etching, to recreate the trenches/recesses. The trenches/recesses can then be filled with any suitable dielectric material in a deposition process to form insulating layer 1119. The insulating layer 1119 can include any suitable dielectric materials including, but not limited to, silicon oxide, silicon nitride, silicon oxynitride, low-k dielectrics, or any combination thereof.

As shown in FIG. 11C, forming transistor layer 1130 can include forming gate electrodes 1135 at one or more lateral sides of vertical semiconductor pillars 1133. In some implementations, gate electrodes 1135 of each row of vertical transistors 1132 along the first lateral direction (x-direction) can be connected with each other to form one word line. Gate electrodes 1135 can include any suitable conductive materials, such as polysilicon, metals (e.g., W, Cu, Al, etc.), metal compounds (e.g., TiN, TaN, etc.), or silicides. For example, gate electrode 1135 may include doped polysilicon, i.e., gate poly. In some implementations, gate electrode 1135 includes multiple conductive layers, such as a W layer over a TiN layer.

As shown in FIG. 11C, forming transistor layer 1130 can further include forming isolation structures 1144 between adjacent vertical semiconductor pillars 1133. In some implementations, isolation structures 1144 can include any suitable isolation materials, such as a thin insulating spacer oxide (TISO) material. In addition, forming transistor layer 1130 can include forming gate dielectric layer 1137 between gate electrodes 1135 and vertical semiconductor pillars 1133. Gate dielectric layer 1137 can include any suitable dielectric materials, such as silicon oxide, silicon nitride, silicon oxynitride, or high-k dielectrics. For example, gate dielectric layer 1137 may include silicon oxide, i.e., gate oxide.

In some implementations, gate electrodes 1135 and gate dielectric layer 1137 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc.).

Referring back to FIG. 10, method 1000 can proceed to operation 1040, in which an array of storage units can be formed on the array of vertical transistors. FIG. 11D illustrates a schematic side cross-sectional view of the 3D memory device in the x-z plane after operation 1040 of method 1000.

As shown in FIG. 11D, a storage unit layer 1150 can be formed. Storage unit layer 1150 can include an array of storage units 1155 each coupled with a corresponding one of the array of vertical transistors 1132. In some implementations, the array of storage units 1155 can be an array of capacitors including a common second electrode, a plurality of first electrode, and a capacitor dielectric layer between the first electrodes and the common second electrode. In some implementations, the first electrodes and/or the common second electrode can include conductive materials including, but not limited to, W, Co, Cu, Al, TiN, TaN, polysilicon, silicides, or any combination thereof. In some implementations, the capacitor dielectric layer includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the array of capacitors can be formed by a series of fabricating processes including thin film deposition processes (e.g., CVD, PVD, ALD, etc.) and patterning processes (e.g., photoetching, dry etching, wet etching, cleaning, CMP, etc.).

Referring back to FIG. 10, method 1000 can proceed to operation 1050, in which the sacrificial interconnects can be replaced by bit line interconnection structures. FIGS. 11E-11G each illustrates a schematic side cross-sectional view of the 3D memory device in an x-z plane at a certain stage of operation 1050 of method 1000.

In some implementations, the 3D structure shown in FIG. 11D can be flipped over. Portions of substrate 1110 can be removed by any suitable process, such as dry etching, wet etching, CMP, etc., to expose the plurality of sacrificial interconnects 1120, as shown in FIG. 11E. As shown in FIG. 11F, portions of substrate 1110 can be further removed by any suitable process, such as dry etching, wet etching, CMP, etc., to expose portions of the insulating layer 1119, vertical semiconductor pillars 1133, and bit lines 1115. A protection layer 1145 can be formed to cover exposed surfaces of vertical semiconductor pillars 1133 and bit lines 1115. In some implementations, protection layer 1145 can include any suitable dielectric material having an etching ratio different from that of the material of sacrificial interconnects 1120 during one or more selective etching processes. For example, protection layer 1145 can include a silicide material. In some implementations, protection layer 1145 can be formed by oxidizing exposed surfaces of vertical semiconductor pillars 1133 and bit lines 1115.

As shown in FIG. 11G, the plurality of sacrificial interconnects 1120 can be removed by any suitable etching process, such as a wet etching process. Protection layer 1145 can protect vertical semiconductor pillars 1133 and bit lines 1115 during the etching process for removing sacrificial interconnects 1120. A conductive material can then be deposited to form bit line interconnection structures 1170. In some implementations, bit line interconnection structures 770 can include any suitable conductive materials, such as polysilicon, metals (e.g., W, Cu, Al, etc.), metal compounds (e.g., TiN, TaN, etc.), or silicides. In some implementations, bit line interconnection structures 770 can include multiple conductive layers, such as a W layer over a TiN layer.

In some implementations, portions of insulating layer 1119, isolation structures 1144, and/or gate electrodes 1135 can be removed to form one or more air gaps 1127. An insulating layer 1160 can be formed to cover protection layers 1145, air gaps 1127, and bit line interconnection structures 1170. The insulating layer 1160 can include any suitable dielectric materials including, but not limited to, silicon oxide, silicon nitride, silicon oxynitride, low-k dielectrics, or any combination thereof.

Referring back to FIG. 10, method 1000 can proceed to operation 1060, in which a conductive layer can be formed to couple with the bit line interconnection structures. FIG. 7H illustrates a schematic side cross-sectional view of the 3D memory device in the x-z plane after operation 1060 of method 1000.

As shown in FIG. 11H, a conductive layer 1180 can be formed in insulating layer 1160 and in contact with bit line interconnection structures 1170. In some implementations, conductive layer 1180 can include one or more BEOL metal layers, and can be formed by any suitable series of fabricating processes including thin film deposition processes (e.g., CVD, PVD, ALD, etc.) and patterning processes (e.g., photoetching, dry etching, wet etching, cleaning, CMP, etc.).

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A memory device, comprising:
an array of memory cells in an array region;
word lines extending parallel in a first lateral direction;
bit lines extending parallel in a second lateral direction different from the first lateral direction; and
interconnection structures located within the array region and coupled with the bit lines, and arranged in staggered rows along the first lateral direction.

2. The memory device of claim 1, wherein:
a first distance between two interconnection structures coupled with two adjacent bit lines is greater than a second distance between the two adjacent bit lines.

3. The memory device of claim 1, wherein:
a first row of interconnection structures are located at a first side of a center position of the array region; and
a second row of interconnection structures are located at a second side of the center position opposite to the first side.

4. The memory device of claim 1, wherein:
a first row of interconnection structures are located at a first side of one word line; and
a second row of interconnection structures are located at a second side of the one word line opposite to the first side.

5. The memory device of claim 1, wherein:
each of the array of memory cells comprises a vertical transistor and a storage unit coupled with the vertical transistor; and
gate structures of each row of vertical transistors aligned along the first lateral direction are connected with each other to constitute a corresponding word line.

6. The memory device of claim 5, wherein the gate structures of each row of vertical transistors are located on a lateral side of channel structures of the row of vertical transistors.

7. The memory device of claim 6, wherein each gate structure laterally surrounds a corresponding channel structure.

8. The memory device of claim 7, further comprising:
a conductive layer connected to first ends of the interconnection structures, wherein second ends of the interconnection structures are connected to the bit lines; and
an insulating layer between the bit lines and the conductive layer, wherein the interconnection structures vertically extend through the insulating layer.

9. A method of forming a memory device, comprising:
forming bit lines extending parallel in a second lateral direction on a semiconductor layer;
forming sacrificial structures each vertically extending through a corresponding bit line and into the semiconductor layer;
forming an array of memory cells on the bit lines;
removing the semiconductor layer to expose portions of the sacrificial structures;
replacing the sacrificial structures with interconnection structures; and
forming a conductive layer coupled with the interconnection structures.

10. The method of claim 9, further comprising:
forming air gaps between adjacent bit lines; and
after removing the semiconductor layer, oxidizing exposed surfaces of the bit lines to form insulating layers.

11. The method of claim 9, wherein forming the sacrificial structures comprises:
forming rows of sacrificial structures aligned parallel along a first lateral direction,
wherein adjacent rows of sacrificial structures are arranged in a staggered form.

12. The method of claim 11, wherein forming the array of memory cells comprises:
forming an array of vertical transistors, each column of the vertical transistors along the second lateral direction are coupled with a corresponding one of the bit lines; and
forming an array of storage units on the array of vertical transistors.

13. The method of claim 12, wherein forming the array of vertical transistors comprises:
forming an array of vertical channel structures on the array of semiconductor pillars; and
forming a conductive structure at a side of a row of the array of vertical channel structures and along the first lateral direction.

14. The method of claim 13, wherein forming the conductive structure comprises:
forming the conductive structure to laterally surround each channel structure in the row.

15. A method of forming a memory device, comprising:
forming bit lines extending parallel in a second lateral direction on a semiconductor layer;
forming interconnection structures each vertically extending through a corresponding bit line and into the semiconductor layer;
forming an array of memory cells on the bit lines;
removing the semiconductor layer to expose portions of the interconnection structures; and
forming a conductive layer coupled with the interconnection structures.

16. The method of claim 15, further comprising:
forming insulating layers on sidewalls of the bit lines; and
forming air gaps between adjacent bit lines.

17. The method of claim 15, wherein:
forming the interconnection structures comprises forming rows of interconnection structures aligned parallel along a first lateral direction; and
adjacent rows of interconnection structures are arranged in a staggered form.

18. The method of claim 17, wherein forming the array of memory cells comprises:
forming an array of vertical transistors, each column of the vertical transistors along the second lateral direction are coupled with a corresponding one of the bit lines; and
forming an array of storage units on the array of vertical transistors.

19. The method of claim 18, wherein forming the array of vertical transistors comprises:
forming an array of vertical channel structures on the array of semiconductor pillars; and
forming a conductive structure at a side of a row of the array of vertical channel structures and along the first lateral direction.

20. The method of claim 19, wherein forming the conductive structure comprises:
forming the conductive structure to laterally surround each channel structure in the row.
